(19) United States
(12) Patent Application Publication
(10) Pub. No.: US 2019/0035628 A1
(43) Pub. Date: Jan. 31, 2019

(54) METHOD AND STRUCTURE FOR REDUCING SUBSTRATE FRAGILITY

(71) Applicants: MASSACHUSETTS INSTITUTE OF TECHNOLOGY, Cambridge, MA (US); NATIONAL UNIVERSITY OF SINGAPORE, Singapore (SG); NANYANG TECHNOLOGICAL UNIVERSITY, Singapore (SG)

(72) Inventors: Li ZHANG, Singapore (SG); Kwang Hong LEE, Singapore (SG); Shuyu BAO, Singapore (SG); Eng Kian Kenneth LEE, Singapore (SG); Eugene A. FITZGERALD, Cambridge, MA (US); Soo Jin CHUA, Singapore (SG); Chuan Seng TAN, Singapore (SG)

(73) Assignees: MASSACHUSETTS INSTITUTE OF TECHNOLOGY, Cambridge, MA (US); NATIONAL UNIVERSITY OF SINGAPORE, Singapore (SG); NANYANG TECHNOLOGICAL UNIVERSITY, Singapore (SG)

(21) Appl. No.: 16/071,654

(22) PCT Filed: Jan. 19, 2017
(86) PCT No.: PCT/SG2017/050029

§ 371 Date: Jul. 20, 2018

Related U.S. Application Data
(60) Provisional application No. 62/280,921, filed on Jan. 20, 2016.

(51) Int. Cl. H01L 21/02

(52) U.S. Cl. CPC H01L 21/02639; H01L 21/02381; H01L 21/0262; H01L 21/0245; H01L 21/0254; H01L 21/02433

(57) ABSTRACT

Method and structure for reducing substrate fragility. In one embodiment, a substrate for metamorphic epitaxy of a material film is provided, the substrate comprising a passivation layer defining a growth window for the material film on a deposition surface of the substrate, the growth window being laterally spaced from an edge of the substrate.

### FIELD OF INVENTION

The present invention relates broadly to a method and structure for reducing substrate fragility, in particular using passivation encapsulating layers or films.

### BACKGROUND

For the growth of III-N materials (i.e. GaN, AN and InN and their alloys) on 50, 100, 150, 200 mm, or even larger Si substrates, it is often discovered that although the tensile strain due to coefficient of thermal expansion (CTE) mismatch has been ameliorated by the strain engineered buffer, the wafer is still fragile during further process handling. The fragility manifests itself e.g. in the GaN-on-Si wafers breaking into large pieces with fairly high frequency during steps involving thermal processing (e.g. anneals, high temperature film deposition/etching etc.) and mechanical handling (e.g. chemo-mechanical polishing, wafer bonding etc.).

As one example, the fragility of 200 mm diameter 725 μm thick GaN-on-Si wafers typically deteriorates by the formation of slip-lines in the Si substrate during the substrate annealing step before the Low Temperature (LT)-AlN deposition. This is due to the presence of vertical and radial temperature variations across the 200 mm Si substrate. The Si crystal slip takes place if the local stress exceeds the yield strength at the annealing temperature (1050° C.) prior to the LT-AlN growth. Specifically, in the growth of GaN on 200 mm diameter 725 μm thickness Si (111) wafers with a shaped susceptor, the Si substrate is suspended by multiple (>2) protrusions on the shaped susceptor. As a result, there are two major sources of stress on the Si substrate in the Metal-Organic Chemical Vapor Deposition (MOCVD) growth of GaN. They are the contact stresses between the protrusions and wafer and the thermal stress due to temperature non-uniformity in the vertical and radial directions.

The slip lines originate from the edge of the wafer and propagate toward the center of the wafer. The origins of slip lines on the edge of the wafer are found to coincide with the positions of the protrusions on the shaped susceptor. The thermal conduction between the protrusions on the shaped susceptor and the Si wafer produces extra radial and vertical thermal stress. There is additional contact stress exerted onto the wafer by the protrusions as well. Minimizing radial temperature differences across the 200 mm Si wafer during growth through the optimization of heater zone settings is one key way to reduce slip formation and wafer fragility. However, it has been found that this, by itself, is insufficient to obtain a high yield of slip-free and non-fragile wafers post-growth.

Embodiments of the present invention seek to address at least one of the above problems.

### SUMMARY

In accordance with a first aspect of the present invention, there is provided a substrate for metamorphic epitaxy of a material film, the substrate comprising a passivation layer defining a growth window for the material film on a deposition surface of the substrate, the growth window being laterally spaced from an edge of the substrate.

In accordance with a second aspect of the present invention, there is provided a wafer comprising the substrate the first aspect, and the material film.

In accordance with a third aspect of the present invention, there is provided a method of fabricating a substrate for metamorphic epitaxy of a material film, the method comprising providing a substrate; and providing a passivation layer on the substrate, the passivation layer defining a growth window for the material film on a deposition surface of the substrate, the growth window being laterally spaced from an edge of the substrate.

In accordance with a fourth aspect of the present invention, there is provided a method of fabricating a wafer, the method comprising performing the method of the third aspect, and providing the material film.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 (a) shows a schematic process flow illustration of III-nitride heteroepitaxy on an encapsulated Si substrate, according to an example embodiment.

FIG. 1 (b) shows a schematic drawing illustrating the substrate resulting from FIG. 1 (a) in a shaped susceptor.

FIG. 2 (a) shows a schematic cross-sectional illustration of the structure of GaN-on-encapsulated Si substrate wafer according to an example embodiment and Nomarski microscopy image of the edge region of the wafer.

FIG. 2 (b) shows a schematic cross-sectional illustration of the structure of conventional GaN-on-Si substrate wafer and Nomarski microscopy image of the edge region of the wafer.

FIG. 3 shows a schematic illustration of a wafer patterned with an array of growth windows defined by oxide stripes, according to an example embodiment. The inset is a zoomed-in optical image of a single growth window of the wafer.

FIG. 4 shows a flowchart illustrating a method of fabricating a substrate for metamorphic epitaxy of a material film, according to an example embodiment.

### DETAILED DESCRIPTION

Embodiments described herein seek to solve wafer fragility issues associated with the heteroepitaxial processes of materials on non-native substrates (e.g. GaN, AlN, and InN materials, as well as their alloys, on Si substrates).

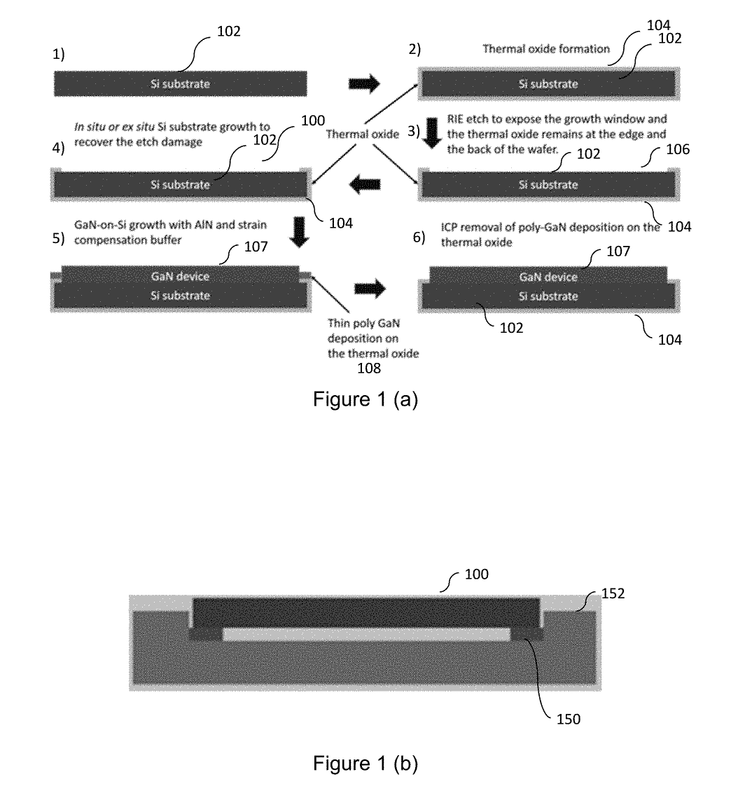

Specifically, a new approach to further minimize the slip line formation is provided in example embodiments, whereby the wafer edge and the bottom of the Si wafer are passivated before the GaN growth. The edges of the wafer often experience the highest stress while having reduced strength due to the presence of dislocations. An engineered Si (111) substrate, as described in more detail with reference to FIG. 1 below in one example embodiment, is prepared by the growth of 140 nm thermal oxide on a standard 200 mm Si (111) wafer, thereby encasing the wafer. The oxide is patterned and dry etched to form a growth window on the front-side of the wafer.

The described embodiments advantageously provide a means to prevent the formation of defects in substrates (e.g. Si) during high temperature processing such as epitaxial growth. Example embodiments are especially pertinent to the metamorphic growth of thin films at high temperature, such as the growth of III-nitrides on Si, where large lattice- and/or coefficient of thermal expansion (CTE) mismatches are present that create significant stresses within the epitaxial films and substrates, resulting in large wafer bow or cracking. By arresting the formation of defects in the substrates, wafer fragility is can preferably be greatly reduced, which leads to much improved yields in both the growth and subsequent processing steps. This is particularly important when dealing with growth and processing on larger wafer sizes.

FIG. 1 (a) shows a schematic process flow illustration of III-nitride heteroepitaxy on encapsulated Si substrate 100, according to an example embodiment. In step 1, a conventional Si substrate or wafer 102 is provided, as understood in the art. In step 2, thermal oxide 104 growth is performed as a passivation layer. In one embodiment, the thermal oxide 104 on the Si substrate 100 can be formed preferably between 900° C. to 1300° C. in dry or wet oxidation condition. The thickness can be controlled by the oxidation time, as will be appreciated by a person skilled in the art. It is noted that other techniques that can form SiO₂ on a Si substrate can be used in different embodiments, e.g. plasma enhanced chemical vapor depositions (PECVD), sputtering, etc. In step 3, Reactive Ion Etching (RIE) is performed to expose a growth window 106 which is laterally spaced from the edge of the Si wafer 102, with the thermal oxide 104 remaining at the edge and the back of the Si wafer 102 in this example embodiment. In one embodiment, a ring with external and internal diameter of 200 mm and 190 mm, respectively can be used as a mask (not shown) during the ME. The ring is placed on the circumference of the thermal oxide Si substrate 100. The exposed thermal oxide region is then removed in a ME tool using CHF₃ as an etchant gas in one embodiment. Prior to the growth of GaN, in situ (in one example embodiment, noting that ex situ methods are also possible in different embodiments) Si homoepitaxial growth is carried out in step 4, to remove surface damage caused by the thermal oxide formation and its removal (in the growth window 106). In step 5, GaN-on-Si growth with AlN and strain compensation buffer is performed to form a GaN device 107, as is understood in the art, noting that a thin poly GaN 108 deposition occurs in the example embodiment outside the growth window 106 on the thermal oxide 104. In step 6, ICP removal of the poly GaN 108 deposition on the thermal oxide 104 is performed. In one embodiment, a hard mask (not shown, for example made form SiO₂ or SiN) is deposited on the entire wafer and a lithography step with the reverse mask polarity as the mask used to open the growth window 106 is applied. The unmasked poly GaN is then selectively etched over the masked GaN device 107. The thermal oxide 104 can be removed, for example by dipping the entire wafer in HF. However, it can be retained in different embodiments, if a thermal oxide layer is preferred in future process.

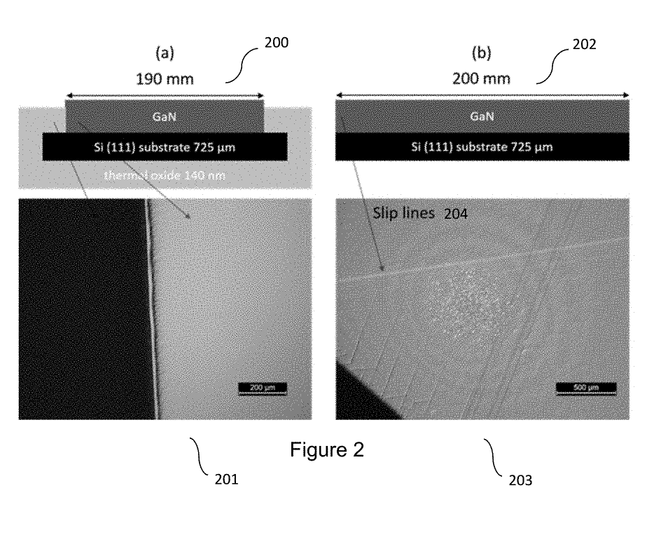

In the example embodiment, since the entire edge of the Si wafer 100 is passivated, nucleation of slip lines from the edge of the Si wafer 100 is advantageously prevented. Additionally, the thermal conduction between the protrusions 150 on a shaped susceptor 152 and the Si wafer 100, as illustrated in FIG. 1 (b) is preferably reduced due to the small thermal conductivity of silicon dioxide. As a result, no slip lines are found in the GaN growth window, as evident from a comparison of the FIGS. 2 (a) and (b). FIG. 2 (a) shows a schematic cross-sectional illustration of the structure of GaN-on-encapsulated Si substrate wafer 200 according to an example embodiment and Nomarski microscopy image 201 of the edge region of the wafer 200, whereas FIG. 2 (b) shows a schematic cross-sectional illustration of the structure of conventional GaN-on-Si substrate wafer 202 and Nomarski microscopy image 203 of the edge region of the wafer 202. As can be seen, no slip lines are visible in the Nomarski microscopy image 201 compared to the Nomarski microscopy image 203, in which slip lines e.g. 204 are clearly visible.

Furthermore, the protrusions on the susceptor are in contact with the thermal oxide 206 masked region (on the underside of the wafer 200, and near its edge) in the example embodiment. This advantageously minimizes the contact stress on the edge of the wafer 200.

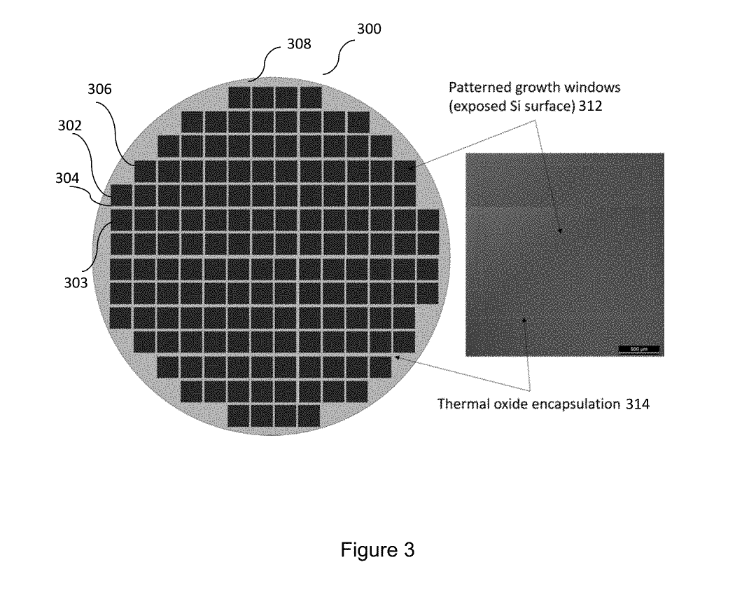

The present invention can be extended to different embodiments to further manage stress build-up due to both CTE- and lattice-mismatch. This can be achieved by forming multiple growth windows after the growth of the thermal oxide as the passivation layer in different embodiments, instead of a single large window as in the embodiments described above with reference to FIGS. 1 and 2. It is noted that a single patterning step is preferably needed regardless of whether a single large growth window or multiple growth windows are formed in different embodiments. FIG. 3 shows a schematic illustration of a wafer 300 with a patterned array of growth windows e.g. 302, 303, the growth windows e.g. 302, 303 being laterally spaced from the edge of the wafer 300 and from each other. The oxide stripes e.g. 304 between adjacent growth windows e.g. 302, 303 prevents GaN from being deposited in those regions during the GaN growth, resulting in the formation of discrete mesas/islands e.g. 306 of GaN material which now advantageously have space in between them to accommodate the epilayer film stresses. It is noted that the poly GaN deposited onto the oxide stripes e.g. 304 usually consists of disconnected GaN islands. There are thus many voids in the poly GaN to prevent strain built-up in the space between the discrete mesas/islands e.g. 306. The spacing between growth windows e.g. 302, 303 can be varied to optimize for stress-relief and useful chip design-area, and the growth windows e.g. 302, 303 can be patterned into arbitrary size and shape as required for a given chip or device design, while the oxide 308 at the edge of the wafer remains intact. The inset 301 is a zoomed-in optical image of a single growth window 312 and thermal oxide encapsulation 314.

While embodiments of the invention were described above as applied to the heteroepitaxial growth of III-nitrides on Si, it is noted that the invention can be applied to the metamorphic epitaxy of any material system where stresses are built-up in the wafer due to lattice- and/or CTE-mismatch according to different embodiments, so as to reduce wafer fragility. The III-nitride system presents one of the greatest challenges in terms of wafer fragility, due to the large mismatches and typical growth on large wafer sizes, which exacerbate stress and bow issues. As mentioned, other material systems can also benefit from reduced wafer fragility in different embodiments of the invention, even though they may generally not face fragility issues to such a large extent where reduced mismatches are present in such systems.

It is noted that while the embodiments above describe the use of Si-oxide as the passivation layer, other materials can be used for the passivation layer in different embodiments, including other dielectric materials. As will be appreciated by a person skilled in the art, passivation layers in the semiconductor industry are commonly dielectrics, for example both nitrides and oxides are commonly used, frequently interchangeably. For example, SiN may be used in different embodiments, while another possibility is Si-oxynitride. SiN as the passivation layer can be formed, for example, by annealing a Si substrate at a temperature between 900° C. to 1400° C. in an N₂ environment. Other SiN deposition techniques, e.g. PECVD, low pressure chemical vapor deposition (LPCVD) can be used in different embodiments. The removal of the SiN in example embodiments is similar to the removal of the oxide as described for the embodiments above. It is noted that for example PECVD dielectric is theoretically conformal, and thus passivates the edges of the wafer in example embodiment. While, compared to thermal (oxide) growth, there may be a larger difference in thickness of the dielectric on the surface of the wafer vs at the edge, this may not be problematic for the passivation requirements according to example embodiments. To form the dielectric on both the back side as well as the front side (i.e. the dielectric ring at the edge of the wafer), two separate deposition steps can be performed using e.g. PECVD in an example embodiment, noting that PECVD deposition is essentially single-sided, as will be appreciated by a person skilled in the art.

In one embodiment, a substrate for metamorphic epitaxy of a material film is provided, the substrate comprising a passivation layer defining a growth window for the material film on a deposition surface of the substrate, the growth window being laterally spaced from an edge of the substrate.

The passivation layer may be configured for prevention of nucleation of slip lines from the edge of the substrate during the metamorphic epitaxy of the material film.

The substrate may comprise an array of growth windows for the material film on the deposition surface of the substrate, the growth windows being laterally spaced from the edge of the substrate and from each other. The passivation layer may be configured for provision of space in between the growth windows to accommodate stresses during the metamorphic epitaxy of the material film.

The passivation layer may be formed around the edge of the substrate and a backside of the substrate opposite the deposition surface.

The substrate may comprise Si.

The passivation layer may comprise a dielectric material. The dielectric material may comprise an oxide or a nitride.

In one embodiment, a wafer is provided comprising the substrate of the above embodiment; and the material film.

The material film and the substrate may exhibit lattice- and/or CTE-mismatch.

The material film may comprise a III-nitride material.

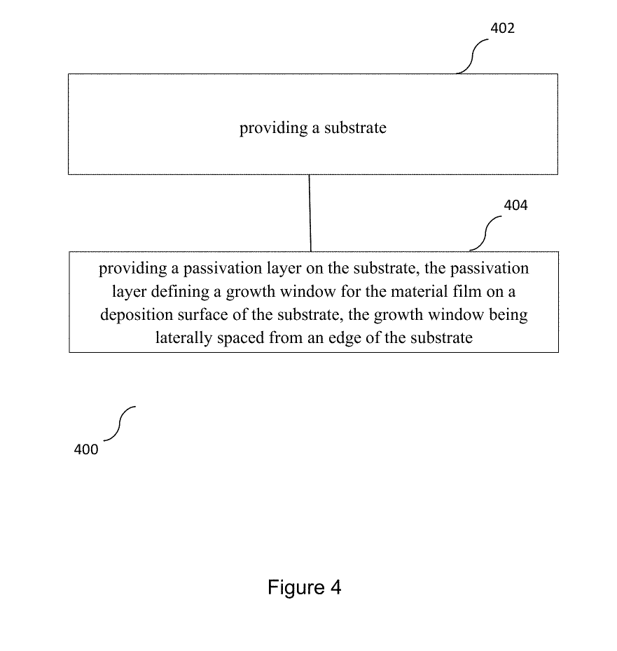

FIG. 4 shows a flowchart 400 illustrating a method of fabricating a substrate for metamorphic epitaxy of a material film, according to an example embodiment. At step 402, a substrate is provided. At step 404, a passivation layer is provided on the substrate, the passivation layer defining a growth window for the material film on a deposition surface of the substrate, the growth window being laterally spaced from an edge of the substrate.

The method may comprise configuring the passivation layer for prevention of nucleation of slip lines from the edge of the substrate during the metamorphic epitaxy of the material film.

The method may comprise providing an array of growth windows for the material film on the deposition surface of the substrate, the growth windows being laterally spaced from the edge of the substrate and from each other. The method may comprise configuring the passivation layer for provision of space in between the growth windows to accommodate stresses during the metamorphic epitaxy of the material film.

Providing the passivation layer may comprise forming the passivation layer around the edge of the substrate and a backside of the substrate opposite the deposition surface.

The substrate may comprise Si.

The passivation layer may comprise a dielectric material. The dielectric material may comprise an oxide or a nitride.

In one embodiment, a method of fabricating a wafer is provided, the method comprising performing the method according to the above embodiment and providing the material film.

The material film and the substrate may exhibit lattice- and/or CTE-mismatch.

The material film may comprise a III-nitride material.

In summary, embodiments of the invention can solve the problem of wafer damage and fragility associated with growing epitaxial films with high lattice- and/or CTE-mismatch, which is especially problematic for large wafer sizes.

Increasing the resistance of substrates/wafers to damage/plastic deformation due to high temperature processing steps, advantageously leads to increased manufacturing yields, which is especially pertinent to Si industry/wafers, due to the large wafer sizes used. Embodiments of the present invention may use, but are not limited to, wafers with a diameter of 50, 100, 150, 200 mm, or larger, or 2″, 3″, 4″, 6″, 8″ or larger.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive. Also, the invention includes any combination of features, in particular any combination of features in the patent claims, even if the feature or combination of features is not explicitly specified in the patent claims or the present embodiments.

1. A substrate for metamorphic epitaxy of a material film, the substrate comprising a passivation layer defining a growth window for the material film on a deposition surface of the substrate, the growth window being laterally spaced from an edge of the substrate.

2. The substrate of claim 1, wherein the passivation layer is configured for prevention of nucleation of slip lines from the edge of the substrate during the metamorphic epitaxy of the material film.

3. The substrate of claim 1, comprising an array of growth windows for the material film on the deposition surface of the substrate, the growth windows being laterally spaced from the edge of the substrate and from each other.

4. The substrate of claim 3, wherein the passivation layer is configured for provision of space in between the growth windows to accommodate stresses during the metamorphic epitaxy of the material film.

5. The substrate of claim 1, wherein the passivation layer is formed around the edge of the substrate and a backside of the substrate opposite the deposition surface.

6. The substrate of claim 1, wherein the substrate comprises Si.

7. The substrate of claim 1, wherein the passivation layer comprises a dielectric material, wherein optionally the dielectric material comprises an oxide or a nitride or an oxynitride.

8. (canceled)

9. A wafer comprising:
the substrate of claim 1; and
the material film.

10. The wafer of claim 9, wherein the material film and the substrate exhibit lattice- and/or CTE-mismatch.

11. The wafer of claim 9, wherein the material film comprises a III-nitride material.

12. A method of fabricating a substrate for metamorphic epitaxy of a material film, the method comprising:
providing a substrate; and
providing a passivation layer on the substrate, the passivation layer defining a growth window for the material film on a deposition surface of the substrate, the growth window being laterally spaced from an edge of the substrate.

13. The method of claim 12, comprising configuring the passivation layer for prevention of nucleation of slip lines from the edge of the substrate during the metamorphic epitaxy of the material film.

14. The method of claim 12, comprising providing an array of growth windows for the material film on the deposition surface of the substrate, the growth windows being laterally spaced from the edge of the substrate and from each other.

15. The method of claim 14, comprising configuring the passivation layer for provision of space in between the growth windows to accommodate stresses during the metamorphic epitaxy of the material film.

16. The method of claim 12, wherein providing the passivation layer comprises forming the passivation layer around the edge of the substrate and a backside of the substrate opposite the deposition surface.

17. The method of claim 12, wherein the substrate comprises Si.

18. The method of claim 12, wherein the passivation layer comprises a dielectric material, wherein optionally the dielectric material comprises an oxide or a nitride or an oxynitride.

19. (canceled)

20. The method of claim 12, further comprising
providing the material film for fabricating a wafer.

21. The method of claim 20, wherein the material film and the substrate exhibit lattice- and/or CTE-mismatch.

22. The method of claim 20, wherein the material film comprises a III-nitride material.
